(19) United States
(12) Patent Application Publication
(10) Pub. No.: US 2013/0028442 A1
(43) Pub. Date: Jan. 31, 2013

(54) Loudspeaker system

(71) Applicants: Yiu Cheung Brian Li, Sham Tseng (CN); Steven Halsall, Tonbridge Wells (GB)

(72) Inventors: Yiu Cheung Brian Li, Sham Tseng (CN); Steven Halsall, Tonbridge Wells (GB)

(73) Assignee: GP Acoustics (UK) Limited, Kent (GB)

(21) Appl. No.: 13/575,185

(22) PCT Filed: Jan. 27, 2011
(86) PCT No.: PCT/GB2011/000108

§ 371 Date: Oct. 8, 2012

(30) Foreign Application Priority Data
Jan. 28, 2010 (GB) 1001350.6

(51) Int. Cl. H03G 5/00

(52) U.S. Cl. 381/98

(57) ABSTRACT

A loudspeaker that can be bi-wired or not according to a user's preference comprises a case in which is provided a plurality of audio drivers supplied by a respective plurality of audio networks, the networks being supplied (in turn) by a respective plurality of input terminal pairs, further comprising at least one switch bridging the terminals of different pairs, and adapted to selectively connect the terminals to each other.

### CROSS-REFERENCE TO RELATED APPLICATION

This Application is a Section 371 National Stage Application of International Application No. PCT/ GB2011/000108, filed Jan. 27, 2011 and published as WO/2011-092471 A1 on Aug. 4, 2011, in English, the contents of which are hereby incorporated by reference in their entirety.

### FIELD OF THE INVENTION

The present invention relates to a loudspeaker system.

### BACKGROUND ART

Many users of audio equipment employ the principle of “bi-wiring” to connect a loudspeaker to an audio amplifier, in order to improve or optimise the output of their audio system. Normally, a single cable (i.e. two conductors) runs from the amplifier output to the terminals of the loudspeaker. From this point, connections are made to the loudspeaker elements, usually via crossover networks. Thus, higher-frequency audio signals are separated within the loudspeaker and supplied to the high-frequency drivers (tweeters) and low-frequency audio signals are separated and supplied to the low-frequency drivers (bass).

In a bi-wired system, two cables (i.e. 2×2 conductors) are run from the amplifier output to the loudspeaker cabinet. One cable supplies the audio signal to a high frequency input and one cable supplies the same audio signal to a separate low frequency input. Each input then supplies the audio signal to their respective driver(s) via their respective crossover networks.

Some within the audio community hold that this improves the sound quality of the system as a whole, by electrically separating the high- and low-frequency signals via the amplifier, which in turn leads to less interference. Others deny this, arguing that the two ways of making connections are electrically equivalent.

### SUMMARY OF THE INVENTION

This debate over the merits of bi-wiring places loudspeaker manufacturers in a difficult position. If they provide only a single pair of terminals then the loudspeakers are made unsuitable to those who wish to bi-wire. If two pairs of terminals are provided in order to cater for bi-wiring, then opponents of bi-wiring can be offended that the manufacturer is (seemingly) indicating its approval of bi-wiring and must make arrangements to short the respective terminals via a suitable wire link.

The present invention therefore provides a loudspeaker, comprising a case in which is provided a plurality of audio drivers supplied by a respective plurality of audio networks, the networks being supplied (in turn) by a respective plurality of input terminal pairs, further comprising at least one switch electrically connected to the terminals of different pairs, and adapted to selectively connect the terminals to each other.

Alternatively, the invention provides a loudspeaker comprising (i) a low-frequency signal input comprising two terminals of a first polarity and a second polarity, a low frequency network connected to the terminals of the low-frequency signal input, and a low-frequency driver connected to the output of the low-frequency network, (ii) a high-frequency signal input comprising two terminals of a first polarity and a second polarity, a high frequency network connected to the terminals of the high-frequency signal input, and a high-frequency driver connected to the output of the high-frequency network, and (iii) a switch arrangement, electrically connected to the two terminals of the low-frequency signal input and to the two terminals of the high-frequency signal input, and comprising at least one element movable between at least two positions, comprising a first position in which the terminals of the low-frequency signal input are isolated from the terminals of the high-frequency signal input, and a second position in which (a) one terminal of the low-frequency signal input is connected to one terminal of the high-frequency signal input and (b) the other terminal of the low-frequency signal input is connected to the other terminal of the high-frequency signal input.

Such a loudspeaker will usually be incorporated within a casing, with the low-frequency network and the high-frequency network being accommodated within the casing, and the low-frequency signal input, the high-frequency signal input, and the switch arrangement all being accessible from outside the casing.

We prefer that in the second position of the switch arrangement, the terminal of the first polarity of the low-frequency signal input is connected to the terminal of the first polarity of the high-frequency signal input and the terminal of the second polarity of the low-frequency signal input is connected to the terminal of the second polarity of the high-frequency signal input.

The switch arrangement can comprise at least two discrete switches, one switch being arranged to connect the terminal of the first polarity of the low-frequency signal input to a terminal of the high-frequency signal input, and a further switch arranged to connect the terminal of the second polarity of the low-frequency signal input to a terminal of the high-frequency signal input. Alternatively, a single switch actuator can be provided with the necessary number of poles.

The switch arrangement can comprise substantially any form of switch in which a moveable or removable element is able to selectively bridge at least a pair of contacts, thereby to create an electrical connection between the two contacts. Examples include a rotary switch, a toggle (dolly) switch, a rocker switch, a push-button switch, or a switch in which a removable element forms part of the electrical conduction path between the contacts, the element being removable by (for example) partially or fully unscrewing from a seat (which may form one of the contacts).

### BRIEF DESCRIPTION OF THE DRAWINGS

An embodiment of the present invention will now be described by way of example, with reference to the accompanying figures in which;

FIGS. 1 and 2 show a conventional bi-wiring-compatible loudspeaker used in a single-wired and a bi-wired mode, respectively;

FIGS. 3 and 4 show a loudspeaker according to the present invention used in a single-wired and a bi-wired mode, respectively;

FIG. 5 shows the electrical circuit of FIGS. 3 and 4;

FIG. 6 shows a panel incorporating the present invention; and

FIG. 7 shows a section through the panel along VII-VII of FIG. 6.

### DETAILED DESCRIPTION OF THE EMBODIMENTS

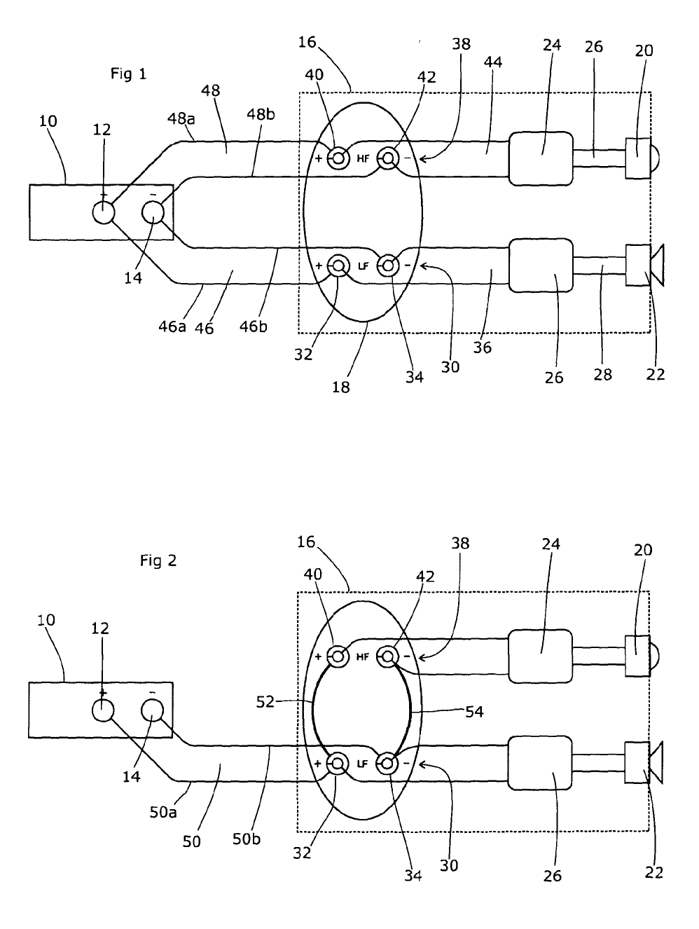

FIGS. 1 and 2 show a known approach to bi-wiring of loudspeakers. An amplifier 10 has a pair of output terminals of a first polarity 12 and a second polarity 14. The loudspeaker 16 has a panel 18 with a plurality of input terminals, a tweeter driver 20 for high-frequency signals, and a base driver 22 for low-frequency signals. The tweeter 20 and the bass driver 22 are driven by appropriate crossover networks 24, 26 respectively. Suitable cabling 26, 28 runs from the appropriate crossover 24, 26 to the relevant driver 20, 22.

The bass crossover 26 is connected to a pair of bass terminals 30 that are presented on the panel 18. These comprise a first polarity bass terminal 32 and a second polarity bass terminal 34, from each of which run at least one conductor of a cable 36 which leads to the bass crossover 26. Likewise, a pair of high-frequency input terminals 38 consist of a first polarity high-frequency terminal 40 and a second polarity high-frequency terminal 42. These are connected via conductors of a cable 44 to the high frequency crossover network 24.

In the bi-wired example shown in FIG. 1, a first two-conductor cable 46 runs from the amplifier 10 to the bass input terminals 30. One conductor 46a runs from the first polarity terminal 12 of the amplifier to the first polarity terminal 32 of the bass input terminals 30, and the second conductor 46b runs from the second polarity amplifier terminal 14 to the second polarity terminal 34 of the bass input terminals 30. Roughly in parallel to the first cable 46 is a second cable 48, which runs from the same amplifier terminals 12, 14 to the high-frequency input terminals 38. As with the first cable 46, this comprises a first conductor 48a which leads from the first polarity amplifier terminal 12 to the first polarity terminal 40 of the high-frequency terminals and a second conductor 48d which runs from the second polarity terminal 14 of the amplifier to the second polarity terminal 42 of the high-frequency terminals 38.

FIG. 2 shows the arrangement adopted when bi-wiring is not desired. The same loudspeaker 16 is instead connected via a single cable 50, comprising a first conductor 50a which leads from the first polarity terminal 12 of the amplifier 10 to either of the first polarity terminals 32, 40. In this case, the conductor is connected to the first polarity terminal 32 of the bass input terminals 30. A second conductor 50b of the cable 50 runs from the second polarity terminal 14 of the amplifier 10 to the corresponding second polarity terminal 34. A pair of link wires 52, 54 are then connected between the respective first polarity terminals 32, 40 and between the second polarity terminals 34, 42. Other forms of conductor might be provided as an alternative, such as pre-formed metal links. These link wires or other links might be fitted to the loudspeaker 16 during manufacture or prior to shipping, in which case they will then be removed by a user who wishes to bi-wire the loud speaker as shown in FIG. 1.

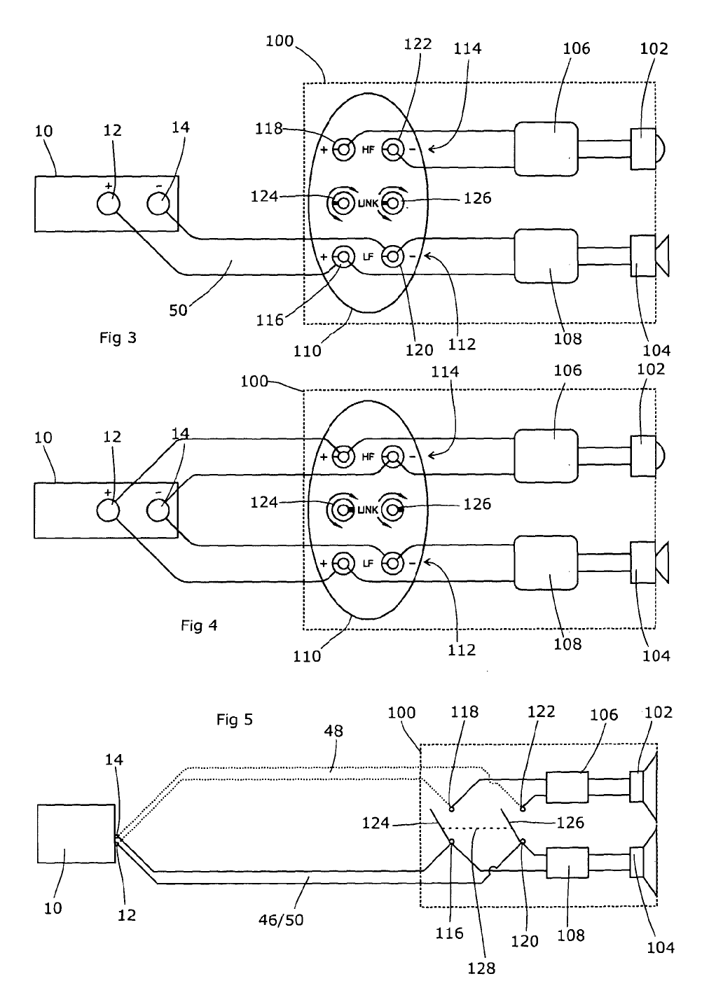

FIGS. 3 to 5 show an arrangement according to the present invention. A loudspeaker 100 comprises a tweeter 102 and a bass driver 104, each supplied by a respective crossover network 106, 108 and internal wiring identical to that of the speaker 16 of FIGS. 1 and 2. Again, there is a panel 110 bearing input terminals, in the form of first and second polarity bass input terminals 116, 120, and first and second polarity high-frequency terminals 118, 122. An externally accessible switch 124 is provided between the two first polarity terminals 116, 118. A similar switch 126 sits in a corresponding situation between the second polarity input terminal 120 of the bass input terminals 112 and the second polarity input terminal 122 of the high-frequency input terminals 114.

FIG. 3 shows the switches 124, 126 in a first position in which the respective pairs of input terminals are electrically connected. This means that only a single cable 50 needs to be connected to the output terminals 12, 14 of the amplifier 10, then can be joined to either the bass input terminals 112 or the high-frequency input terminals 114. In this case, the cable 50 is shown connected to the bass input terminals 112. The signal is however still supplied to the high-frequency crossover 106 via the link switches 124, 126.

FIG. 4 shows the arrangement adopted if bi-wiring is desired. A pair of cables 46, 48 supply signals separately to the bass input terminals 112 and the high-frequency input terminals 114 respectively, and the link switches 124, 126 are put into a second position (as shown) in which the two sets of input terminals are electrically isolated. Thus, electrically, the situation is identical to a bi-wire arrangement such as is shown in FIG. 1. However, in order to achieve the single-wired arrangement shown in FIGS. 2 and 3, no additional wire links 52, 54 are necessary.

FIG. 5 shows the corresponding electrical circuit. Switches 124, 126 can be single pole single throw switches if desired. They act between the respective pairs of first polarity input terminals 116, 118 and second polarity input terminals 120, 122, and serve to short them selectively. Thus, where there is only a single cable 50 leading from the amplifier then to the input terminals of the loud speaker 100, the link switches 124, 126 can be closed thereby supplying a signal to both the bass crossover 108 and the high-frequency crossover 106 regardless of which pair of terminals the cable is connected to. If a pair of cables 46, 48 are provided then the link switches 124, 126 can be opened thereby ensuring there is no link between the respective pairs of input terminals within the loud speaker 100, and separate signals are provided to each of the two crossover networks 106, 108 via the separate cable 48, 46.

FIGS. 3 and 4 show a pair of rotary switches 124, 126. Other forms of switches could be used such as toggle switches, rocker switches or latching push-button switches (or other forms of push-button switch). Alternatively, as indicated in FIG. 5 by a dotted line 128, the two switch functions could be integrated into a single double-pole switch which may be of any type as above.

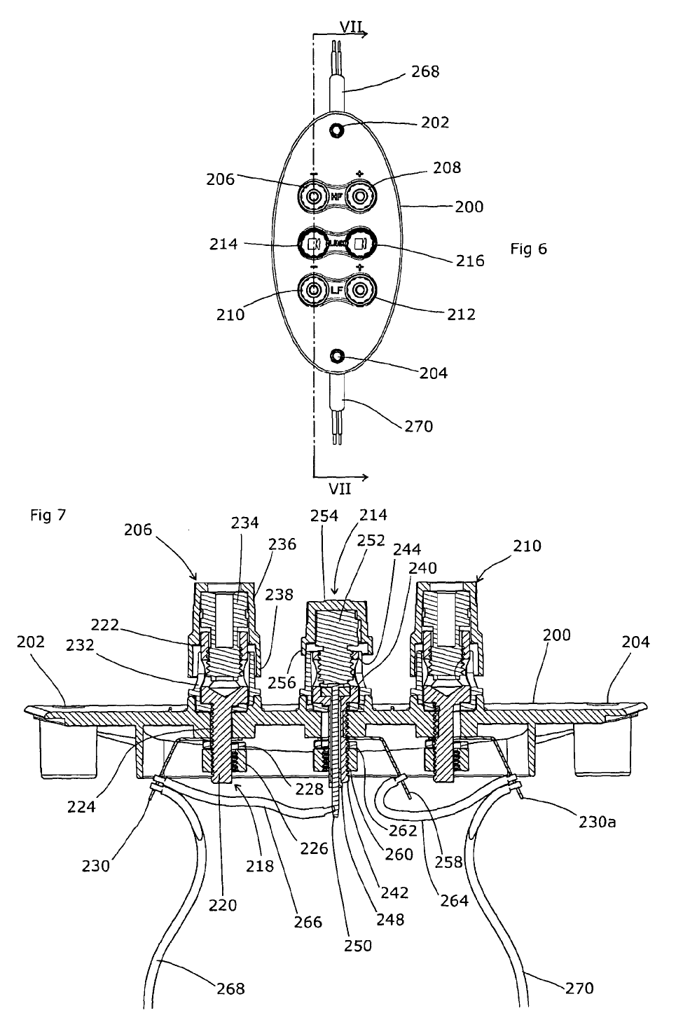

FIGS. 6 and 7 show a possible commercial embodiment of the invention. A fascia panel 200 is provided for the various terminals and switches, and may be manufactured as a discrete item for fitting to a suitable aperture on the loudspeaker cabinet, or may be part of the cabinet itself. In this instance, the fascia panel 200 is a discrete item and has a pair of fixing holes 202, 204 to receive a suitable fixing such as a screw, bolt or rivet in order to secure it in place on the cabinet.

The fascia panel 200 carries a pair of HF terminals 206, 208 which feed a signal to a high-frequency network elsewhere within the loudspeaker. Spaced from the HF terminals 206, 208 are a like pair of LF terminals 210, 212 which feed a signal to a low-frequency network.

A pair of switch terminals 214, 216 are positioned between the HF terminals 206, 208 and the LF terminals 210, 212 in order to control the bi-wiring status of the loudspeaker as described above. Each switch terminal 214, 216 controls one polarity of the respective HF and LF terminals. As illustrated in FIG. 6, the six terminals are arranged in a 2×3 grid with the HF terminals 206, 208 in one pair at one end of the grid, the LF terminals 210, 212 in a further pair at the opposite end of the grid, and the switch terminals 214, 216 in a pair located between and aligned with the LF and HF terminals. This gives an aesthetically pleasing arrangement in which the nature of each terminal is intuitively apparent to most users. This is reinforced by suitable indicia moulded into, printed on, or otherwise applied to the fascia panel 200, such as “HF” between the HF terminals 206, 2058, “LF” between the LF terminals 210, 212, and “LINK” between the switch terminals 214, 216. Other layouts and/or indicia can be adopted, of course.

FIG. 7 shows a sectional view along one HF terminal 206, one switch terminal 214, and one LF terminal 210, all of the same polarity. The other three terminals are identical in construction to the three shown in FIG. 7, differing only in their location on the fascia panel 200 and in that they supply a signal to the other polarity input of the respective high- and low-frequency networks.

The HF terminal 206 and the LF terminal 210 are also identical in construction. Referring to the HF terminal 206, each comprises a contact 218 having an externally threaded lower rod-shaped section 220 and an internally threaded upper cylindrical section 222. The lower rod-shaped section 220 is the narrower, and therefore the contact 218 can be secured to the fascia panel 200 by passing the rod-shaped section 220 through a suitable bore 224 and securing the contact 218 in place with a nut 226 and washer 228 on its external thread. A conductive tab 230 is fitted over the rod-shaped section 220 in advance, and is then sandwiched between the washer 228 and the fascia panel 200, in electrical contact with the contact 218, to provide a convenient means of electrical connection to the contact 218.

The upper cylindrically-shaped section 222 has a transverse through-hole 232 adjacent the lower blind end of its interior space. This allows the conductor of a signal cable to be inserted into the interior space via the through-hole. An externally threaded plug 234 can then be driven down via the internal threading of the cylindrical section 222 in order to trap the conductor against the blind end of the interior space and/or the edges of the through-hole 232 in order to establish a good electrical connection between the conductor and the contact 218. An insulating cap 236 can be fitted on the plug 234 to provide a grip to assist in rotation, which can have a flared skirt 238 around the cylindrically-shaped section 222 to protect it from the environment and provide a neat external appearance.

The switch terminal 214 has a contact 240 that is similar to the contact 218, but in which the lower rod-shaped section 242 has a longitudinal internal bore that extends from the interior space of the upper cylindrical section 244 to the free lower end of the lower rod-shaped section 242. An insulating liner 248 is fitted within the longitudinal bore, and surrounds a conductive pin 250. This has a head portion seated at the base of the interior space of the upper cylindrical section 244, but insulated therefrom by the liner 248, and an elongate section that extends within the liner 248 and projects from the end of the lower rod-shaped section 242.

A plug 252 is provided for the upper cylindrical section 244, similar in form to the plug 234. When screwed fully home into the upper cylindrical section 244, it makes contact instead with the head of the conductive pin 250. As the threaded sections of the upper cylindrical section 244 and the plug 252 are in contact, this will create an electrical connection between the contact 240 and the conductive pin 250. Likewise, when the plug 250 is partially or fully unscrewed, the contact 240 and the conductive pin 250 will become isolated from each other. As with the HF and LF terminals 206, 210, an insulating cap 254 is provided for the plug 250 and has a flared skirt 256 for the cylindrically-shaped section 244.

A tab 258 is fitted to the lower rod-shaped section 242 and sandwiched between the fascia panel 200 and a retaining nut 260 and washer 262, to provide a convenient conductive electrical contact with the lower rod-shaped section 242.

It then only remains to the provide a short wire link 264 between the tab 258 of the switch terminal 214 and the tab 230a of the LF terminal 210, and a second short wire link 266 between the projecting part of the conductive pin 250 and the tab 230 of the HF Both wire links will then be located behind the facsia panel 200, providing a neat external appearance. The switch terminal 214 can then act as a switch enabling the choice of a single- or bi-wired configuration, as described above. Connections can be made to one of the LF and HF terminals, or both, as desired. Cables 268 and 270 connected to the tabs 230, 230a of the HF and LF terminals will convey the signals to the relevant network elsewhere within the loudspeaker.

Through the present invention, the need for link cables or other link conductors 52, 54 is avoided. The rear of the speaker is therefore less complex and less messy, and there is less opportunity to lose the links if (for example) the speaker is initially set up in a bi-wired arrangement and is later converted to a single-wired arrangement

It will of course be understood that many variations may be made to the above-described embodiment without departing from the scope of the present invention.

1. A loudspeaker comprising;
a low-frequency signal input comprising two terminals of a first polarity and a second polarity, a low frequency network connected to the terminals of the low-frequency signal input, and a low-frequency driver connected to the output of the low-frequency network;
a high-frequency signal input comprising two terminals of a first polarity and a second polarity, a high frequency network connected to the terminals of the high-frequency signal input, and a high-frequency driver connected to the output of the high-frequency network;
a switch arrangement, electrically connected to the two terminals of the low-frequency signal input and to the two terminals of the high-frequency signal input, and comprising at least one element movable between at least two positions, comprising a first position in which the terminals of the low-frequency signal input are isolated from the terminals of the high-frequency signal input, and a second position in which (a) one terminal of the low-frequency signal input is connected to one terminal of the high-frequency signal input and (b) the other terminal of the low-frequency signal input is connected to the other terminal of the high-frequency signal input.

2. The loudspeaker according to claim 1 further comprising a casing, the low-frequency network and the high-frequency network being accommodated within the casing, and the low-frequency signal input, the high-frequency signal input, and the switch arrangement all being accessible from outside the casing.

3. The loudspeaker according to claim 1 in which, in the second position of the switch arrangement, the terminal of the first polarity of the low-frequency signal input is connected to the terminal of the first polarity of the high-frequency signal input and the terminal of the second polarity of the low-frequency signal input is connected to the terminal of the second polarity of the high-frequency signal input.

4. The loudspeaker according to claim 1 in which the switch arrangement comprises at least two discrete switches, one switch being arranged to connect the terminal of the first polarity of the low-frequency signal input to a terminal of the high-frequency signal input, and a further switch arranged to connect the terminal of the second polarity of the low-frequency signal input to a terminal of the high-frequency signal input.

5. The loudspeaker according to claim 1 in which the switch arrangement comprises at least one rotary switch.

6. The loudspeaker according to claim 1 in which the switch arrangement comprises a removable element which forms part of an electrical conduction path between a pair of contacts, the element being removable by partially or fully unscrewing from a seat.

7. The loudspeaker according to claim 6 in which the seat forms one of the contacts.

8. A loudspeaker, comprising a case in which is provided a plurality of audio drivers supplied by a respective plurality of audio networks, the networks being supplied (in turn) by a respective plurality of input terminal pairs, further comprising at least one switch electrically connected to the terminals of different pairs, and adapted to selectively connect the terminals to each other.

9. (canceled)

10. The loudspeaker according to claim 2 in which, in the second position of the switch arrangement, the terminal of the first polarity of the low-frequency signal input is connected to the terminal of the first polarity of the high-frequency signal input and the terminal of the second polarity of the low-frequency signal input is connected to the terminal of the second polarity of the high-frequency signal input.

11. The loudspeaker according to claim 2 in which the switch arrangement comprises at least two discrete switches, one switch being arranged to connect the terminal of the first polarity of the low-frequency signal input to a terminal of the high-frequency signal input, and a further switch arranged to connect the terminal of the second polarity of the low-frequency signal input to a terminal of the high-frequency signal input.

12. The loudspeaker according to claim 3 in which the switch arrangement comprises at least two discrete switches, one switch being arranged to connect the terminal of the first polarity of the low-frequency signal input to a terminal of the high-frequency signal input, and a further switch arranged to connect the terminal of the second polarity of the low-frequency signal input to a terminal of the high-frequency signal input.

13. The loudspeaker according to claim 2 in which the switch arrangement comprises at least one rotary switch.

14. The loudspeaker according to claim 3 in which the switch arrangement comprises at least one rotary switch.

15. The loudspeaker according to claim 4 in which the switch arrangement comprises at least one rotary switch.

16. The loudspeaker according to claim 2 in which the switch arrangement comprises a removable element which forms part of an electrical conduction path between a pair of contacts, the element being removable by partially or fully unscrewing from a seat.

17. The loudspeaker according to claim 3 in which the switch arrangement comprises a removable element which forms part of an electrical conduction path between a pair of contacts, the element being removable by partially or fully unscrewing from a seat.

18. The loudspeaker according to claim 4 in which the switch arrangement comprises a removable element which forms part of an electrical conduction path between a pair of contacts, the element being removable by partially or fully unscrewing from a seat.
